(19) United States
(12) Patent Application Publication
(10) Pub. No.: US 2017/0045252 A1
(43) Pub. Date: Feb. 16, 2017

(54) OPERATIONAL PERFORMANCE-WEIGHTED REDUNDANCY FOR ENVIRONMENTAL CONTROL SYSTEMS

(71) Applicant: Vigilent Corporation, Oakland, CA (US)

(72) Inventors: Clifford C. Federspiel, El Cerrito, CA (US); James Sheridan, Oakland, CA (US); Dan Mascola, San Francisco, CA (US)

(73) Assignee: Vigilent Corporation, Oakland, CA (US)

(21) Appl. No.: 15/340,713

(22) Filed: Nov. 1, 2016

Related U.S. Application Data
(63) Continuation of application No. PCT/US2015/029302, filed on May 5, 2015.
(60) Provisional application No. 61/988,720, filed on May 5, 2014.

(51) Int. Cl. F24F 11/00; H05K 7/20; H05K 7/14; G06Q 10/00

(52) U.S. Cl. CPC F24F 11/006; F24F 11/0012; G06Q 10/20; H05K 7/20836; H05K 7/1498; F24F 2011/0061

(57) ABSTRACT

A method of obtaining an operational redundancy value, for a system having a plurality of environmental maintenance modules for maintaining an environmental value within a specified range, includes monitoring the modules while the modules are running, to receive operational data regarding a level of operation of each of the modules. The method also includes determining an operational weight for each of the modules based on the operational data of each of the modules, computing an available capacity of the system based on the operational weights of the modules, and determining a required capacity for the system to maintain the environmental value within the specified range when a load exists for the modules. The method also includes calculating the operational redundancy value based on the available capacity and the required capacity and providing a message based on the operational redundancy value.

### CROSS-REFERENCE TO RELATED APPLICATIONS

This application is a continuation of PCT Application No. PCT/US2015/029302, filed May 5, 2015, which claims priority to U.S. Provisional Patent Application No. 61/988,720, filed May 5, 2014. Both of the above-identified applications are hereby incorporated by reference in their entireties for all purposes.

### BACKGROUND

The present invention generally relates to environmental control systems, such as heating, ventilation, and air conditioning (HVAC) systems, which can be used to control the temperature and humidity of common spaces, e.g., as can exist in data centers containing server computers. More, specifically the present invention can relate to efficiently maintaining certain environmental conditions by increasing or decreasing an operation level (e.g. starting and stopping) of respective units (modules) of an environmental control system.

Modern datacenters use HVAC systems to control indoor temperature, humidity, and other variables. It is common to have many HVAC units deployed throughout a data center. They are often floor-standing units, but may be wall-mounted, rack-mounted, or ceiling-mounted. The HVAC units also often provide cooled air either to a raised-floor plenum, to a network of air ducts, or to the open air of the data center. The data center itself, or a large section of a large data center, typically has an open-plan construction, i.e. no permanent partitions separating the air in one part of the data center from the air in another part. Thus, in many cases, these data centers have a common space is temperature-controlled and humidity-controlled by multiple HVAC units.

HVAC units for data centers are typically operated with decentralized, stand-alone controls. It is common for each unit to operate in an attempt to control the temperature and humidity of the air entering the unit from the data center. For example, an HVAC unit may contain a sensor that determines the temperature and humidity of the air entering the unit. Based on the measurements of this sensor, the controls of that HVAC will alter operation of the unit in an attempt to change the temperature and humidity of the air entering the unit to align with the set points for that unit.

For reliability, most data centers are designed with an excess number of HVAC units. Since the open-plan construction allows free flow of air throughout the data center, the operation of one unit can be coupled to the operation of another unit. The excess units and the fact that they deliver air to substantially overlapping areas provides redundancy, which ensures that if a single unit fails, the data center equipment (servers, routers, etc.) will still have adequate cooling.

### BRIEF SUMMARY

Embodiments of the present invention provide systems and methods for evaluating operational redundancy of a system based on environmental maintenance modules (e.g. HVAC units). In various embodiments, a system can heat and/or cool an environment. Sensors can measure temperatures, power consumption and other information at various points within the environment. The calculated operational redundancy values are useful tools for evaluating the likelihood that the system can withstand extreme events and/or component failures and still keep an environmental value such as temperature within a desired range.

In an embodiment, a method of obtaining an operational redundancy value for a system including a plurality of environmental maintenance modules for maintaining an environmental value within a specified range includes monitoring the plurality of environmental maintenance modules, while the environmental maintenance modules are running, to receive operational data regarding a level of operation of each of the plurality of environmental maintenance modules. The method also includes determining an operational weight for each of the plurality of environmental maintenance modules based on the operational data of each of the environmental maintenance modules, computing an available capacity of the system based on the operational weights of the plurality of environmental maintenance modules, and determining a required capacity for the system to maintain the environmental value within the specified range when a load exists for the plurality of environmental maintenance modules. The method also includes calculating the operational redundancy value based on the available capacity and the required capacity and providing a message based on the operational redundancy value. In a further embodiment, a computer product includes instructions for implementing the method. Still further embodiments are directed to systems and computer readable media associated with methods described herein.

A better understanding of the nature and advantages of embodiments herein may be gained with reference to the accompanying drawings and remaining portions of the specification, including the claims. In the drawings, like reference numbers can indicate identical or functionally similar elements.

### BRIEF DESCRIPTION OF THE DRAWINGS

FIG. 1 schematically illustrates layout of a data center, showing environmental maintenance modules that provide cooling for the data center, in an embodiment.

FIG. 2 is a schematic diagram of a computer room air handling unit (AHU), according to an embodiment.

FIG. 3 schematically illustrates layout of a data center, showing environmental maintenance modules that maintain one or more environmental values for the data center, according to an embodiment.

FIGS. 4A-4C are flowcharts that illustrate methods for calculating and utilizing operational redundancy values, according to embodiments.

FIG. 5 is a temperature vs. time plot that illustrates an example of an extreme-temperature event.

FIG. 6 schematically illustrates computer subsystems that can implement techniques described herein, according to an embodiment.

### TERMS

An “environmental maintenance system” may include any system for controlling the environment of a space (an “environmentally-controlled space”). Environmental maintenance systems can include one or more “environmental maintenance modules” such as heating, ventilation, and air conditioning (HVAC) units, air handling units (AHUs), computer room air conditioner (CRAC) units, etc. Each of the environmental maintenance modules may include one or more sensors.

A “sensor” may include any device that measures a quantity at a location. For example, a sensor may measure temperature, humidity, pressure or flow of a liquid or gas, speed of a motor, electrical current, voltage or power consumption, etc. In some cases, a sensor may be a part of an environmental maintenance module. In other cases, a sensor may be standalone; for example, it may not be integrated or associated with a specific environmental maintenance module.

“Operational data” may include any number, percentage, or other quantity that measures, or is calculated from measurements of, the operation, effect, efficiency or operational health of an environmental maintenance system. For example, raw data from a sensor may be considered operational data; similarly, statistics derived from such data (e.g., heat extraction rate for an airflow, calculated from incoming temperature, final temperature, and flow rate of the airflow) are also operational data. An example of operational data based on other operational data is a “Coefficient of Performance” (COP). COP is an operational performance metric for a piece of equipment that quantifies its actual performance; in the case of a cooling unit, COP may be expressed as a ratio of the unit's cooling rate with its power consumption.

“Available capacity” means a number or capacity of one or more environmental maintenance modules in terms of their current ability to maintain a desired appropriate environmental value. In some implementations, environmental maintenance modules that are known to be operating with some degree of impairment maybe counted towards available capacity. In other embodiments, an impaired module is counted partially toward available capacity, with its contribution only counted to the degree of its impaired capacity, such as being weighted with a Coefficient of Performance (COP) of less than a design capacity for the impaired module, or a measured value such as heat transfer capacity.

### DETAILED DESCRIPTION

Redundancy is often employed in a variety of systems to ensure performance to critical specifications, so that if the systems have one component fail, others can carry the load without the single failure starting a whole system failure. In environmental maintenance systems, redundancy often takes the form of installing more heating or cooling subsystems than “should be” necessary to heat or cool a physical space.

Embodiments herein recognize that a further layer of security can be realized by not simply relying on redundancy as installed, but rather by periodically evaluating and calculating operational redundancy, taking into account measured status and/or health of the heating or cooling systems, as well as the actual load on those systems. The general concept of redundancy will be discussed first, followed by introduction of operational redundancy principles and calculations.

### I. Redundancy

To ensure that an environment (e.g. a data center) is sufficiently cool or warm, standard operating procedure is to deploy, and sometimes operate, extra HVAC units (or other environmental maintenance modules) beyond what is marginally required. Recommended levels of system redundancy (for all types of data center infrastructure, including that of heating/cooling systems, hereinafter called environmental maintenance modules) for data centers are specified in industry standard documents such as TIA-942, the Telecommunications Industry Association's Telecommunications Infrastructure Standard for Data Centers. TIA-942 assigns “tiers” to data center facilities that depend on various factors including environmental maintenance module redundancy.

Tier 1 data centers need only have enough design capacity to meet the data center's needs under nominal operating conditions. If a number of environmental maintenance modules that is adequate to meet such needs when operating at design capacity is defined as a number N, then the Tier 1 requirement is for N modules. Tier 2 data centers require at least some design redundancy in case of an environmental maintenance module failure; the Tier 2 requirement is for N+1 modules. Tier 3 and Tier 4 data center environmental maintenance module redundancy requirements vary depending on architecture of the modules (e.g., whether they derive power from common sources and/or reject heat to other units in a laddered approach); redundancy of up to 2(N+1) modules is required in certain cases.

Thus, generally speaking, redundancy in cooling systems and electric power systems of mission-critical facilities is traditionally defined as the total number of units installed minus the number of units required to service the load, assuming each unit operates at its design operating point. Redundancy is traditionally expressed in terms of the number of redundant units. Examples are N+1, N+2, or 2N, where N is the number of units required to service the load. In a mission-critical cooling or power distribution application such as data center cooling, telecom office cooling, or cellular site cooling, redundancy is a necessary feature to guarantee uptime in the event of a cooling unit failure. The traditional definition of redundancy is a design metric. It does not account for the fact that cooling units and uninterruptible power supply (UPS) units degrade with time and use.

### II. Operational Redundancy

Embodiments can use an operational redundancy metric that accounts for performance degradation of environmental maintenance modules (e.g., cooling units, heating units, UPS units, etc.) over time. This redundancy metric can be correlated with failure so that alerts and warnings can be dispatched to operators when the level of operational redundancy has reached a low enough threshold to indicate high risk. Thus, equipment maintenance can be performed as an optimized, quantitative tradeoff between cost and risk. Furthermore, the energy-saving benefits of maintaining equipment to reduce risk can be factored in to offset the cost of maintenance.

A performance-based (e.g., operational) redundancy metric can improve capacity planning. For example, a colocation operator ideally knows quantitatively (not just as a design assumption) if there is enough excess cooling capacity to sell additional information technology (IT) services to a new customer. The new IT services will produce additional heat that must be extracted. If the traditional design redundancy calculation were used to determine excess capacity that could be sold, it might cause the colocation operator to sell poorly performing capacity with a high likelihood of cooling system failure in the future.

Embodiments of operational redundancy can analyze data from sensors throughout an environment (e.g., sensors within environmental maintenance modules, sensors at locations outside of modules, or internal health check or self-diagnostic information from the modules) to determine actual operational health of specific modules. An operational redundancy value is then calculated, in embodiments, starting with actual operational data for specific modules and deriving an available capacity metric for the entire system, instead of basing redundancy calculations on assumptions such as design capacities of the modules. This metric may be called the Redundancy Value (RV). Related metrics express redundancy in various terms, such as number of redundant modules deployed, percentage of redundancy as a percentage of total modules deployed, redundancy in terms of heat transfer capacity, and the like.

The operational redundancy value thus varies according to the operational health of the modules, and can also vary according to a load presented to the system (e.g., heat generated by data center equipment that must be removed). In certain embodiments, load is estimated or assumed, while in other embodiments, load is calculated from measured parameters (such as electrical power consumed by data center equipment). With a calculation or estimation of load in place, a required capacity to meet the load can be calculated, again taking into account the actual operational data for specific modules. The operational redundancy value can provide valuable insight into the effective redundancy of the system; for example the operational redundancy value can be calculated in real time and used to alert appropriate personnel when it drops below a threshold, or can be calculated based on data for a historical period to correlate to system performance over the historical period.

Embodiments can be used to know when a cooling or power system is at risk of failing. In the case of cooling systems, this risk could be caused by too much heat generation from IT equipment, by performance degradation of cooling equipment, or both. Embodiments can also be used to alert a data center service provider about the risk of selling capacity that is not healthy, therefore helping avoid a customer outage. Embodiments can also enable maintenance optimization to manage risk of failure. For example, instead of maintaining all equipment on a scheduled basis, an operator can maintain cooling or power equipment to within an acceptable level of risk, thereby achieving lower energy consumption while avoiding unnecessary maintenance costs. For colocation data centers, embodiments allow the colocation operator to maximize revenue without incurring too much risk of a customer outage due to cooling system or power system failure.

The performance-weighted redundancy value can be based on performance measurements that can be readily acquired and installed. Embodiments can be applied to cooling systems of all sizes and configurations, from very large data centers with hundreds of cooling units to small, cellular base stations that typically have just two air-conditioners and an outdoor air economizer fan.

The performance-weighted redundancy value can be easily understood by a cooling system operator. The values of the performance-weighted redundancy value can be presented in traditional redundancy terms (e.g., N+1, N+2, 2N, 2(N+1)) and they can be directly related to compliance with design standards such as TIA-942, supra. Alternatively, the performance-weighted redundancy value can be presented as a ratio or percentage, either of the number of cooling units or of the amount of cooling capacity. Another advantage is that embodiments yield one or more metrics that are actionable for the user and may be used for “what-if” type scenarios to determine a more cost effective repair strategy than traditional unit counting.

The techniques herein do not require an automatic control system. Advantageously, a monitoring and alerting/reporting system are used, but are not essential. For example, the disclosed metrics can be calculated based on historical data and/or correlated to known thermal events, to support business decisions about implementing additional environmental module capacity.

Certain embodiments benefit from more instrumentation than is typically factory-installed in cooling units. In particular, for certain types of cooling equipment, such embodiments benefit from power monitoring instrumentation and/or flow monitoring instrumentation.

### III. System Overview

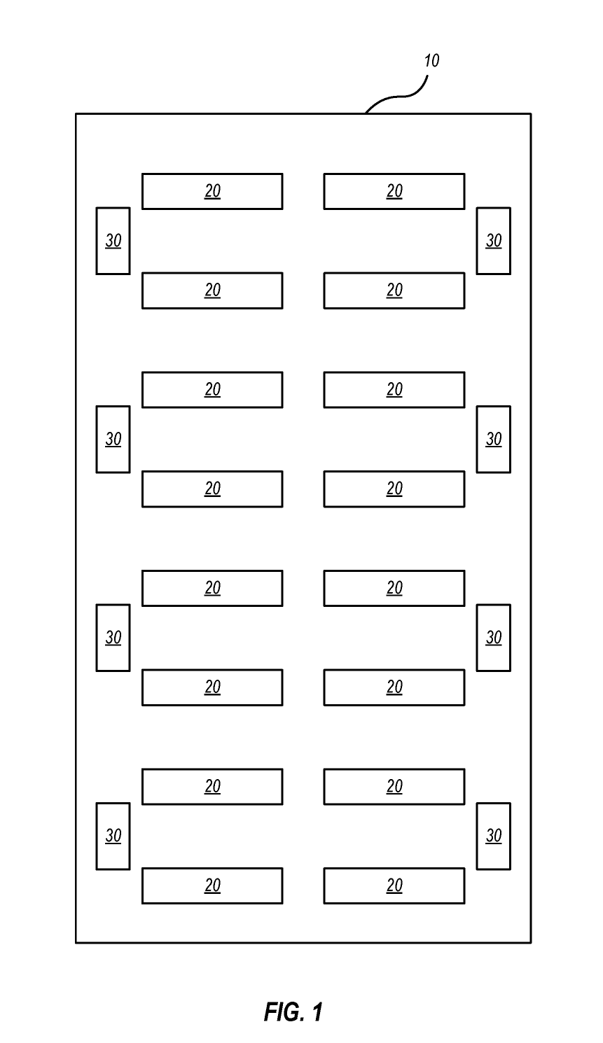

FIG. 1 schematically illustrates layout of a data center 10, showing environmental maintenance modules 30 that maintain one or more environmental values for the data center, in an embodiment. FIG. 1 shows data center 10 in plan view, with server racks 20 for data processing, and environmental maintenance modules 30 that maintain one or more environmental values within data center 10. Typically, server racks 20 generate heat while processing data, and environmental maintenance modules 30 remove the heat, but in embodiments, modules 30 may provide heat rather than remove it, and/or may maintain other environmental values such as humidity of data center 10. It is also understood that modules 30 may be positioned in any manner within data center 10. For example, modules 30 may be placed within data center 10 as shown, may be placed in other locations, and/or may be remotely located, with supply and return ducts of modules 30 being located within data center 10 as appropriate.

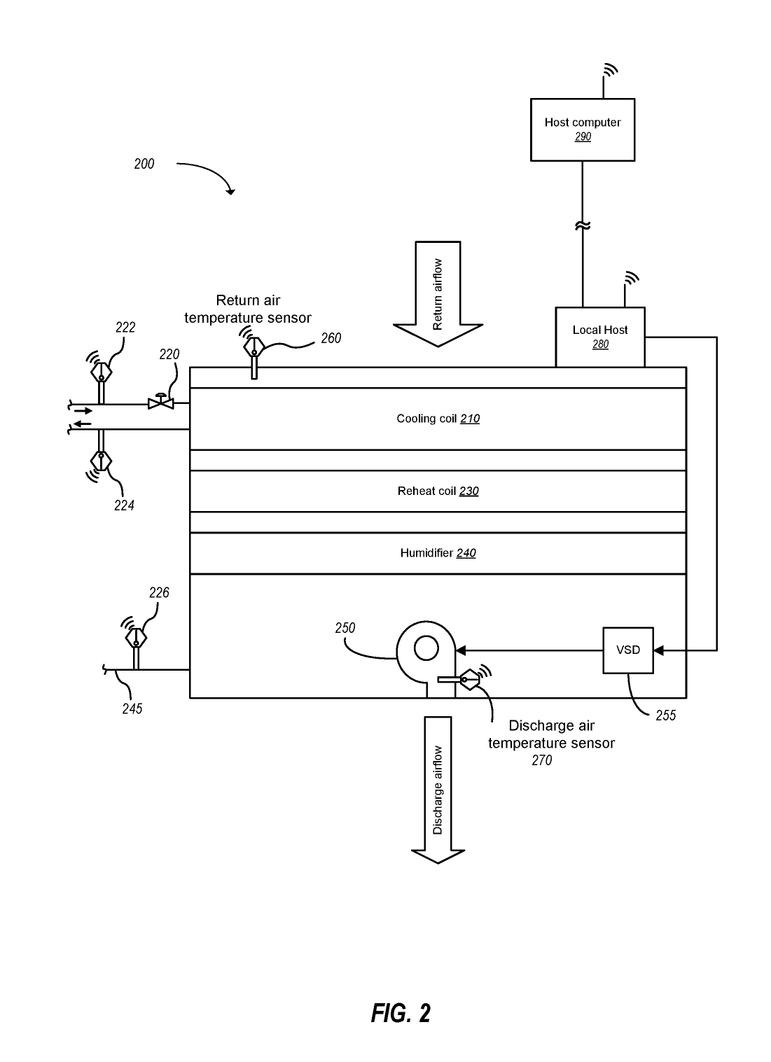

FIG. 2 is a schematic diagram of a computer room air handling unit (AHU) 200, according to an embodiment. Computer room AHU 200 is an example of environmental maintenance module 30, FIG. 1. As shown, computer room AHU 200 has a cooling coil 210, which may contain chilled water modulated by a chilled water valve 220. Supply and/or return legs of the chilled water supply may be monitored by temperature sensors 222, 224. Alternatively, an AHU 200 may be a stand-alone unit in terms of heat dissipation capability, that is, it may operate separately from other modules, with its own condenser, compressor and the like. AHU 200 also has an optional reheat coil 230 (e.g. an electric coil) and an optional humidifier 240 (e.g. an infrared humidifier). Consumption of electrical power of AHU 200 from an electrical power connection 245 may be monitored by an optional sensor 226.

In one embodiment, fan 250 is a centrifugal fan driven by an alternating current (A/C) induction motor. The induction motor may have a variable speed (frequency) drive (VSD) 255 for changing its speed. An optional sensor 260 measures return air temperature, and an optional sensor 270 measures discharge air temperature.

Sensors 222, 224, 226, 260 and/or 270 may be for example wireless sensors that acquire and transmit information wirelessly, or they may be connected via wires or optical (e.g., fiber optic) connections; for example, sensors 222, 224, 270 and 260 may be probes tethered to a local host 280.

Sensors 222, 224, 226, 260 and/or 270 send information to a host computer 290. It should be understood that host computer 290 receives information from more than one set of sensors 222, 224, 226, 260 and/or 270 and is thus typically located remotely from AHU 200, but in embodiments host computer 290 may form part of, or be located with, one AHU 200 while receiving temperature information from sensors of other AHUs 200. In one example, sensors 222, 224, 226, 260 and/or 270 transmit wirelessly through a wireless network gateway to host computer 290. In another example, sensors 222, 224, 226, 260 and/or 270 pass at least some part of the information to local host 280, which relays the temperature information to host computer 290, either wirelessly or through wired or optical connections. Alternatively, some of the information can be passed directly from sensors 222, 224, 226, 260 and/or 270 to host computer 290, while other information is transmitted first to local host 280 and relayed to host computer 290. In other embodiments, AHU 200 has capability to monitor itself, and formulates one or more operational health and/or self-diagnostic metrics that can be used in place of raw data from sensors to determine operational health of AHU 200.

Host computer 290 monitors the information received from AHUs 200 and calculates an operational redundancy value for the system that includes AHUs 200 (e.g., data center 10). The operational redundancy value, sometimes referred to herein as a Coefficient of Redundancy or RV, is calculated based on operationally weighted performance of each AHU 200, instead of a heat extraction design specification or capacity of each AHU 200. The operationally weighted performance is based on sensor data (e.g., from sensors 222, 224, 226, 260 and/or 270) or operational health and/or self-diagnostic metrics of each AHU 200. Each AHU 200 may perform above or below its stated heat extraction design capacity, and performance of an AHU 200 typically degrades over time due to a variety of wearout mechanisms.

An operational redundancy value may be based on theoretical load on the system, or on one or more measurements of system load. For example, when the system is a data center that requires cooling, the load may be measured by assessing power consumed by the data center, or by measuring and adding the heat removed by the AHUs. The load may be expressed in terms of an equivalent number of AHUs required to remove the heat, with excess AHUs being considered redundant.

### IV. Calculation of Operational Redundancy Value

A. Modules Operating Separately

An example calculation of a redundancy value assumes a number T of environmental maintenance modules, in this case cooling units, of similar capacity operate separately from one another in terms of heat dissipation capability. For example, each cooling unit may have a dedicated condenser. There may be other aspects in which the modules operate together, such as being controlled by a common control system, have a common power source and the like, but efficiency of each unit does not depend significantly on efficiency of the other units. This case is illustrated for example in FIG. 1 with the assumption that each environmental maintenance module 30 operates separately from other modules 30. Without loss of generality, these units will be referred to in this example as AHUs.

Part of the redundancy value calculation involves calculating a number of available environmental maintenance modules, S, based on the number and operational condition of the modules that are present and operating. Sensors that evaluate performance of each AHU provide information to a host computer, which calculates a coefficient of performance (COP) or weight Wᵢ associated with each AHU i (where i is an index value). Certain COP calculations and appropriate values are specified in standards such as the American Society of Heating, Refrigerating, and Air-Conditioning Engineers (ASHRAE) Standard 90.1.

The weights used to define S can be computed based on the measured performance of the cooling units relative to a standard or expectation. In certain embodiments, Wᵢ has a value from zero (the AHU is effectively broken, it removes no heat) to 1 (the AHU is performing at its design capability). In other embodiments, Wᵢ may be allowed to have a value greater than one (the AHU's performance exceeds its design capability). For a direct-expansion cooling unit, the weight can be a function of the coefficient of performance (COP) of the unit. Thus, Wᵢ may be a ratio of a heat extraction rate in thermal kilowatts (kWt) to its electrical consumption (kWe). In embodiments, Wᵢ may be calculated in other ways such as averaging over time, or as a binary function that compares a COP of AHU i with a minimum performance threshold, MinStdCOP. In these embodiments, Wᵢ=1 when COP>MinStdCOP, otherwise Wᵢ=0. The performance threshold MinStdCOP can be determined in a variety of ways, such as basing MinStdCOP on design capacity of the AHU, evaluating the kWt/kWe ratio and the like. For example, a useful value of MinStdCOP is the minimum standard level defined by ASHRAE Standard 90.1. For a medium-capacity, air-cooled direct-expansion (DX) unit, this value is 2.1, meaning that the cooling rate of the unit (kWt) should be at least 210% of the electrical energy consumption of the unit (kWe). Units with a COP below MinStdCOP are said to be poorly performing. They are operating with a sub-standard level of efficiency.

Alternatively, in embodiments, MinStdCOP could be variable, and dependent on exogenous variables such as outdoor air temperature, return air temperature, discharge air temperature, or any other parameter that affects the performance (e.g., COP) of the cooling unit. Then MinStdCOP could be defined as a fraction of the expected COP.

Partial or complete failure of a cooling unit is known to have an adverse impact on COP, which is why COP is a good choice for a DX cooling unit. To attenuate noise, COP may be computed as the average or sum of heat extraction rate over a period of time divided by the average or sum of electrical energy consumption over the same period of time. For DX cooling units, the weights can be a binary function of the COP, a linear function of the COP, or any other monotonically increasing function of the COP.

A weight Wᵢ can also be a calculated or modeled probability that an environmental maintenance module will continue to operate for an additional period of time. This probability is typically called a survival function, and could be a function of the COP or exogenous variables such as a type, make, or model of environmental maintenance module.

Having determined Wᵢ for each AHU i, an effective number S of AHUs at the system level is:

S=Σᵢ₌₁^{T}Wᵢ Eq. 1

In embodiments, to provide a conservative measure of redundancy, S may be truncated to the nearest integer.

Next in the calculation of a redundancy value is determination of a load L and its expression as a required capacity to maintain the environmental value (e.g., temperature). In embodiments, L is determined in terms of equivalent AHUs required by first calculating a cooling rate hᵢ for each AHU i, typically averaging the cooling rate over some time interval. A sum of the cooling rates hᵢ provides a net cooling rate H:

H=Σᵢ₌₁^{T}hᵢ Eq. 2

For systems that use environmental maintenance modules with identical design capacity, H is divided by the design capacity, (and optionally, for a conservative measure, rounded up to the nearest integer) to get L, representing the required capacity:

L=int(H/(design capacity))+1 Eq. 3

For systems that use environmental maintenance modules with differing heat extraction design specifications or capacities, required capacity L is the largest number of available cooling units that are collectively required to provide cooling rate H. In these embodiments, AHUs are considered in increasing order of design capacity, that is, the available units with the lowest capacity are considered first. Design capacity of each AHU is subtracted from H until the result is negative, with required capacity L being the number of AHUs subtracted to obtain the first negative result. This is a conservative result because it makes L as large as possible, leaving fewer AHUs left over for redundancy.

Once L is determined, the operational redundancy value RV is determined as:

RV=S−L Eq. 4

The operational redundancy value RV can be interpreted to provide useful conclusions about the system that it characterizes. A negative RV implies that poorly performing units are carrying the burden of maintaining the environmental value. Negative RV implies a high level of operational risk. That is, the system may be unable to maintain the environmental value at all; if it does, even a slight degradation in performance or any additional load may make the system unable to maintain the environmental value. An RV that is greater than or equal to zero, but less than a number of redundant units desired for the type of system being characterized, means that there is less redundancy available than is desired. While the system may be operating normally, it does not have the robustness normally expected for the type of system or for its design intent. Such levels of RV imply a medium level of operational risk. An RV that meets or exceeds the number of redundant units desired for the type of system being characterized implies an acceptable level of operational risk.

The operational redundancy value can also be computed using physical units of heat transfer, or as a percentage of total units or of total cooling capacity. When computed using units of heat transfer, the operational redundancy value may be designated as RVₕ; computed as a percentage of total units it may be designated as RVᵤ; computed as a percentage of total cooling capacity it may be designated as RV_{c}. By extension, calculation of RV for other types of systems would involve determining and converting actual results of system components over time, and calculating corresponding sums and/or ratios of the quantities that are exemplified by calculations related to cooling systems in Eqs. 5-8 below.

The operational redundancy value RV as computed according to Eq. 4 above is an integer value of redundant cooling units, and the variable RV as used herein without a subscript is assumed to refer to RV as computed by Eq. 4. However, in embodiments, it is also possible to calculate an operational redundancy value in other terms. For example, to compute an operational redundancy value in units of heat transfer (e.g., kWt), first an available cooling capacity Sₕ in heat transfer units (e.g., kWt) is calculated using the following equation:

Sₕ=Σᵢ₌₁^{T}WᵢCᵢ Eq. 5

where Cᵢ is the design capacity of cooling unit i in units of heat transfer (e.g., kWt).

Then RVₕ is computed by the following equation:

RVₕ=Sₕ−Σᵢ₌₁^{L}Cᵢ Eq. 6

where the values of C in Eq. 6 are sorted in ascending order as the index i goes from 1 to the load L, as described above.

To compute an operational redundancy value in units of percent of total units, certain embodiments use the following equation:

$${RV}_{u} = \frac{S - L}{T} \qquad Eq . 7$$

where S, L and T are as described above.

To compute an operational redundancy value in units of percent of total cooling capacity, certain embodiments use the following equation:

$${RV}_{c} = \frac{{RV}_{h}}{{\sum }_{i = 1}^{T} {C}_{i}} \qquad Eq . 8$$

B. Modules Operating in Hierarchical Designs

Some systems of environmental maintenance modules (such as, but not limited to cooling systems) have a hierarchical design. In such cases where the environmental maintenance modules are cooling systems, cooling units extracting heat from the controlled space are served by other units that extract heat from the controlled-space cooling units to the atmosphere. One example of this design is a system where direct-expansion (DX) space cooling units are served by one or more dry coolers. A second example of this design is a system where chilled water space cooling units that are served by one or more chiller plants (e.g., as shown in FIG. 2, where each space cooling unit rejects heat to a cooling water loop). For this general discussion, units that directly interface with the environment being controlled are the environmental maintenance modules, while the units above them in the hierarchy are referred to as master units. To calculate RV for a hierarchical cooling system design, the performance weights of the master units at the top of the hierarchy (e.g., dry coolers or chiller plants) must be coupled with (multiplied by) performance weights of the environmental maintenance modules (e.g., space cooling units) that they serve.

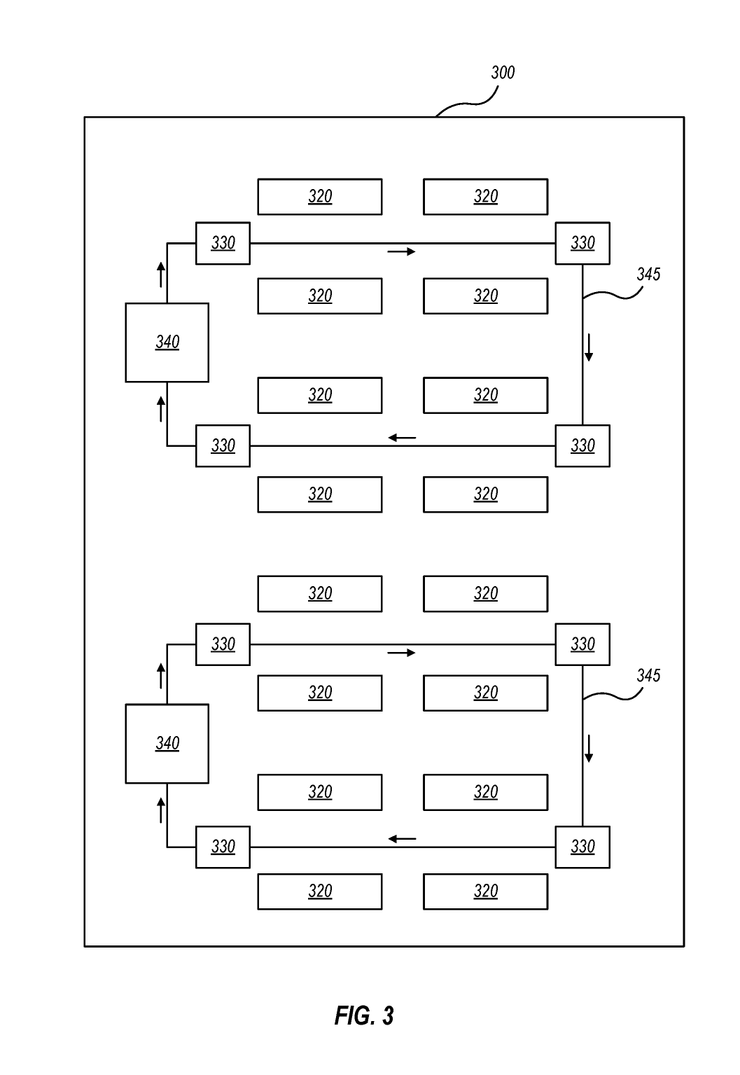

Consider a system in which eight environmental maintenance modules are served by two master units, and assume without loss of generality that one master unit serves four of the modules while a second master unit serves modules another four of the modules. FIG. 3 schematically illustrates layout of a data center 300, showing environmental maintenance modules 330 that maintain one or more environmental values for the data center, in an embodiment. FIG. 3 shows server racks 320 for data processing, which generate heat. FIG. 3 also shows eight environmental maintenance modules 330 and two master units 340 that supply cooling water through chilled water loops 345. Each master unit 340 and its respective chilled water loop 345 serves four environmental maintenance modules 330, as shown. For the case shown in FIG. 3, the number of available environmental maintenance modules serving the controlled space would be computed as follows:

S=W_{D,1}Σᵢ₌₁⁴W_{C,i}+W_{D,2}Σᵢ₌₅⁸W_{C,i} Eq. 9

where the D subscript refers to a particular one of the master units 340, and the C subscript refers to a particular one of the environmental maintenance modules 330. The weights of the master units 340 can be computed in a similar manner to the weights of environmental maintenance modules that operate separately from one another, where the weight can be a function of a COP or similar metric (e.g., heat transfer divided by power consumption), or another performance metric such as expected cooling rate of the master unit 340. If an expected cooling rate were used instead of, or in addition to COP, its value could be dependent on exogenous variables such as outdoor temperature and humidity.

### V. Applications of Operational Redundancy Value

The operational redundancy values calculated herein can be used to characterize robustness of systems in a wide variety of proactive and reactive ways. For example, in an embodiment, environmental maintenance modules of a system can be monitored in real time, operational weights for each of the modules can be determined, and available capacity can be calculated from the operational weights. A load on the system can be measured or assumed, and an operational redundancy value can be calculated based on a difference between the available capacity and required capacity to meet the load.

The operational redundancy value can form the basis of messages to a system operator. In particular, the operational redundancy value can be compared to one or more thresholds to assign an alert level to the system, and the messages may include only the alert, or may also contain the operational redundancy value itself, and/or related information about specific environmental maintenance modules, system loads and the like. Messages may be sent in the form of items displayed on a computer monitor, or may be telephone or Web based alerts such as emails, text messages, and the like.

For example, as noted above, a negative operational redundancy value implies that poorly performing units are carrying the burden of maintaining the environmental value, and implies a high level of operational risk. A system that calculates an operational redundancy value can compare the result to zero and assign a “Red” alert level (or other color or label) based on the operational redundancy value being negative. A message may be sent to the system operator when the assigned alert level is one of a selected subset of alert levels. For example, a message might include the system level “Red” alert as well as indications of which environmental maintenance modules are performing poorly, abnormal load conditions and the like. The operator might be prompted to take actions such as reducing load, turning on additional environmental maintenance modules, notifying a supervisor and the like. An RV that is greater than or equal to zero, but less than a number of redundant units desired for the type of system being characterized, means that there is less redundancy available than is desired, and implies a medium level of operational risk. A system that calculates RV can compare the result to zero and/or a desired number of redundant units, assign a “Yellow” alert level (or other color or label) based on RV being in this range. The system may provide similar messages based on selected alert levels to prompt similar responses by the operator as those discussed above. Similar actions can be taken on the basis of operational redundancy values other than the unsubscripted RV.

An RV that meets or exceeds the number of redundant units desired for the type of system being characterized implies an acceptable level of operational risk. A system that calculates RV can compare the result to a desired number of redundant units, and assign a “Green” alert level (or other color or label) based on RV being in this range. An RV that significantly exceeds the number of redundant units desired for the type of system being characterized implies both an acceptable level of operational risk and a possibility that some units of excess capacity could be shut down (e.g., to reduce operational cost, or for maintenance), but still leave the system with enough redundancy to maintain the acceptable level of operational risk. A system that calculates RV can compare the result to a desired number of redundant units, and assign a “Blue” alert level (or other color or label) based on RV being in this range. Similar actions can be taken on the basis of operational redundancy values other than the unsubscripted RV.

In another embodiment, a monitoring business can implement a monitoring system as a service to a data center business. The monitoring business may add sensors to existing environmental maintenance modules and/or access information already available from the modules, periodically calculate an operational redundancy value, send messages and/or alerts, store the operational redundancy value calculations or provide other services that help the data center business manage its environmental maintenance resources.

In another embodiment, operational redundancy values can be generated from historical data of a system, and the operational redundancy values (and/or alerts generated from the values) can be correlated to system events such as failures. In this embodiment, correlation of operational redundancy values to system events can be used to inform decision-making about investments in system capacity (e.g., whether to invest in additional environmental maintenance modules or master units) and/or monitoring capacity (e.g., whether to invest in sensing and analysis equipment that can produce operational redundancy values and alerts in real time).

In still another embodiment, operational redundancy values can be generated based on combinations of historical data of a system, and assumptions about the system, as “what if” exercises. For example, data center operators generally strive to sell or rent as much space in data centers as possible, but use of such space may be constrained by the data center's ability to remove heat from both existing and proposed operations, with or without redundant capacity. If load L is expressed in terms of a number of environmental maintenance modules sufficient to meet a cooling need (e.g., see Eqs. 2 and 3 above) and a desired number of redundant units R is a desired number of environmental maintenance modules required for an expected level of redundancy (as per an applicable tier requirement in TIA-942), then an excess number of cooling units E can be expressed as:

E=T−L−R Eq. 10

E thus represents cooling capacity that can be considered available to meet cooling needs for new equipment that may be added to a data center, or as additional redundancy/security for existing IT equipment. When addition of servers to an existing data center is considered, it is highly advantageous to evaluate E utilizing actual data for the data center, to minimize the chances that unwarranted assumptions may be made about the cooling capacity. If some of what appears to be excess capacity is poorly performing, it should not be sold until the performance of the environmental maintenance modules has been brought back up above a minimum standard level indicative of sound operation. A number of available or allowable units out of the excess that can be sold, denoted as A, is equal to the maximum of S−L−R or 0:

A=max(0,S−L−R) Eq. 11

In yet another “what if” exercise, operational redundancy values may be calculated from operational data as shown in the above equations, but with weights Wᵢ of specific environmental maintenance modules excluded from the calculation of available cooling capacity S. When S calculated in this manner is then utilized in Eq. 4 to generate RV, the value of RV reflects the operational redundancy that would exist if the specific environmental maintenance modules were not operating. The resulting value of RV can then be utilized to understand how much redundancy would remain in the system should the specific modules be taken offline for repair or replacement.

The specific details of the specific aspects of the present invention may be combined in any suitable manner without departing from the spirit and scope of embodiments of the invention. However, other embodiments of the invention may be directed to specific embodiments relating to each individual aspects, or specific combinations of these individual aspects.

It should be understood that the present invention as described above can be implemented in the form of control logic using computer software in a modular or integrated manner. Software may be stored, for example, in non-transitory, computer readable media, and when executed by a processor, will cause the processor to execute calculations and methods such as discussed above. Based on the disclosure and teachings provided herein, a person of ordinary skill in the art will know and appreciate other ways and/or methods to implement the present invention using hardware and a combination of hardware and software.

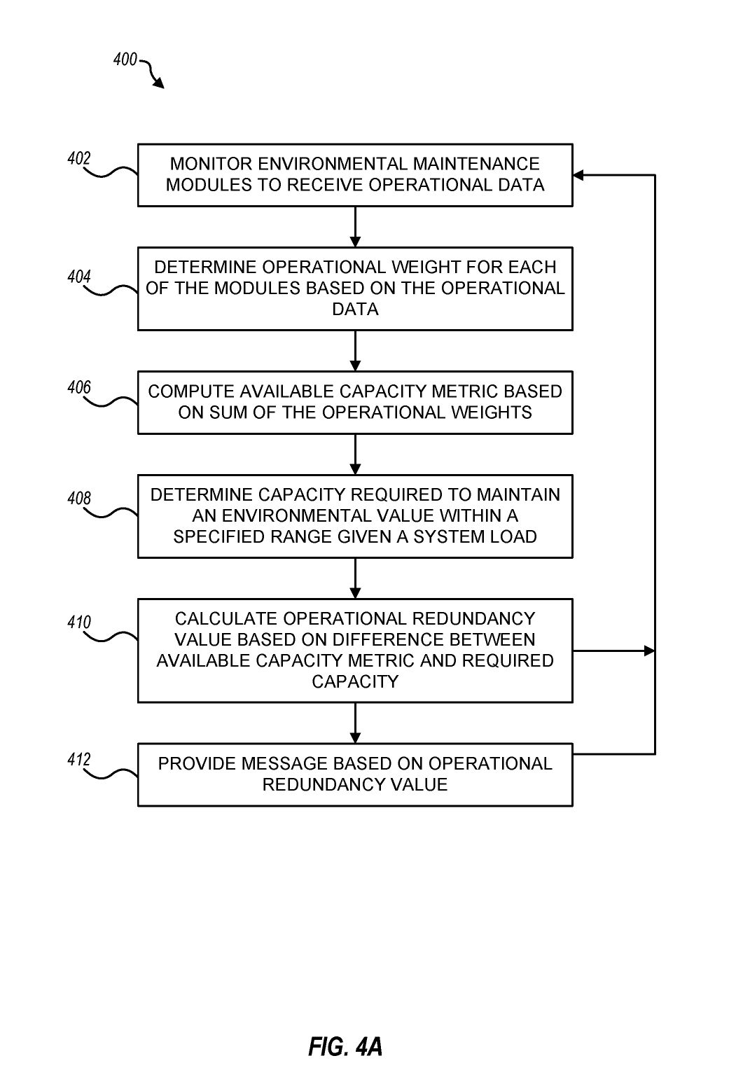

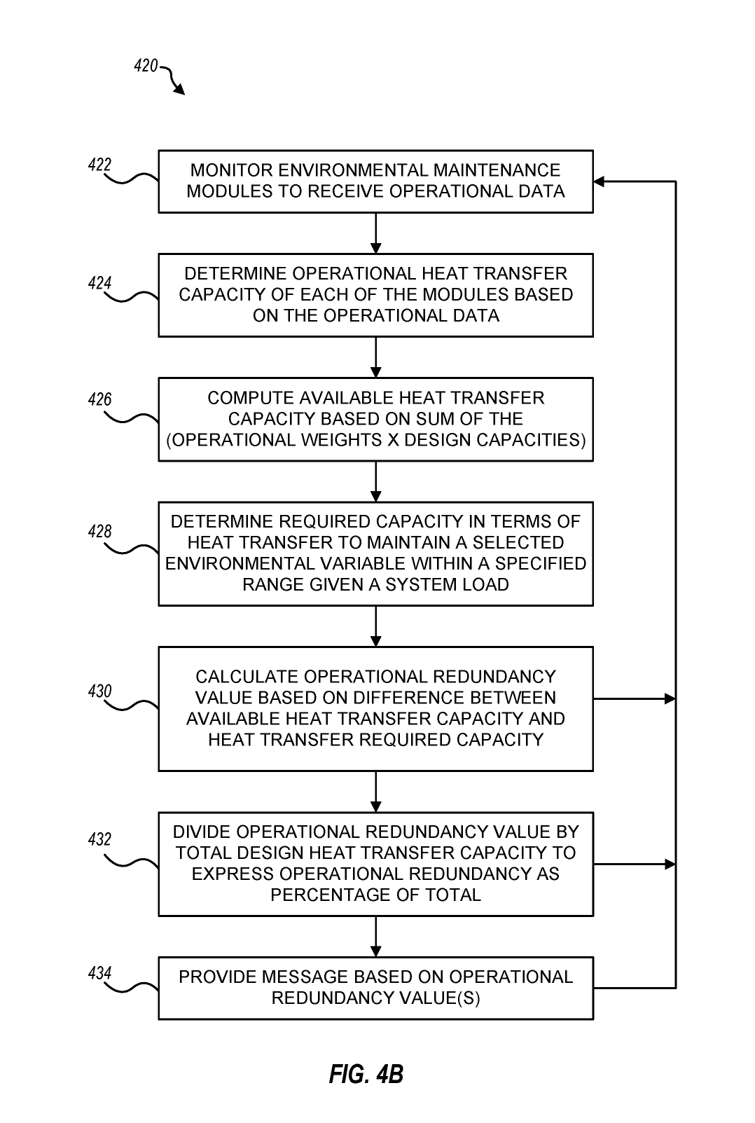

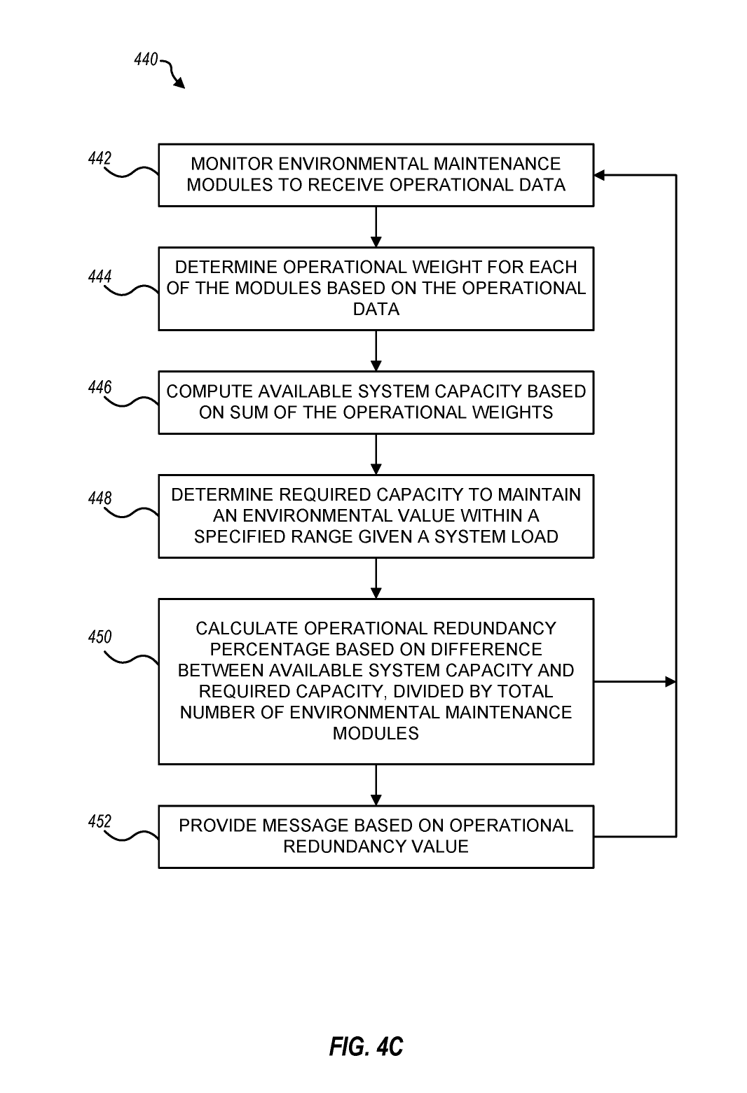

FIG. 4A is a flowchart that illustrates a method 400 for calculating and utilizing operational redundancy value RV according to Eq. 4 above, that is, a calculation of how many redundant environmental modules are available, given operational health of the modules and the current load presented to them. Method 400 and any of the methods described herein may be totally or partially performed with a computer system including one or more processors, which can be configured to perform the steps. Thus, embodiments are directed to computer systems configured to perform the steps of any of the methods described herein, potentially with different components performing a respective step or a respective group of steps. Although presented as numbered steps, steps of methods herein can be performed at a same time or in a different order. Additionally, portions of these steps may be used with portions of other steps from other methods. Also, all or portions of a step may be optional. Any of the steps of any of the methods can be performed with modules, circuits, or other means for performing these steps.

A step 402 monitors environmental maintenance modules to receive operational data. Step 402 may be done in real time or may be done by gathering stored data from the environmental maintenance modules. The operational data may be raw data from sensors of the environmental maintenance modules, or may be one or more operational health and/or self-diagnostic metrics provided by the environmental maintenance modules. An example of step 402 is receiving data from any of sensors 222, 224, 226, 260 and/or 270, FIG. 2, or receiving one or more operational health and/or self-diagnostic metrics provided thereby.

A step 404 determines an operational weight Wᵢ for each of the environmental maintenance modules based on the operational data. An example of step 404 is calculating the operational weights from the operational data, utilizing a lookup table to determine the operational weights from the operational data, or comparing the operational data with one or more thresholds to determine the operational weights Wᵢ.

A step 406 computes an available capacity metric for the system based on a sum of the operational weights Wᵢ. An example of step 406 is adding together the operational weights Wᵢ to form a value of S (Eq. 1). S is the effective number of cooling units that are operating to some minimal performance standard; that is, S is an operational value not a design assumption.

A step 408 determines a system capacity that is required to maintain an environmental value within a specified range, given a system load. The load may be measured or estimated. An example of step 408 is calculating a load L (Eq. 3) expressed as a number of environmental maintenance modules required to maintain the environmental value.

A step 410 of method 400 calculates an operational redundancy value based on a difference between the available capacity metric and the required system capacity. One example of step 410 is subtracting L from S to form a redundancy value RV (as per Eq. 4 above); other examples include expressing available capacity and load in differing units that relate to module performance, and calculating appropriate sums and/or ratios thereof, as per Eqs. 5-8 above.

Method 400 optionally returns to step 402 after step 410, but in embodiments, an optional step 412 provides a message based on the operational redundancy value. In embodiments, the message is simply storage of the calculated operational redundancy value; alternatively, the message may be display of the operational redundancy value, and/or an alert based thereon, to an operator of the system. If optional step 412 is performed, method 400 thereafter returns to step 402.

FIG. 4B is a flowchart that illustrates a method 420 for calculating and utilizing an operational redundancy value RVₕ and/or RV_{c}, according to Eqs. 6 and 8 above. As noted above, RVₕ is a calculation of how much redundant heat transfer capability exists to maintain a selected environmental variable, given operational health of environmental maintenance modules and the current load presented to them, while RV_{c} expresses the redundant heat transfer capability as a percentage of available heat transfer capability. Like method 400, method 420 may be partially or totally performed with a computer system including one or more processors, modules, circuits, or other means configured to perform the steps thereof. Method 420 and/or a computer system configured to perform its steps may potentially use different components to perform a respective step or group of steps at a same time or in a different order, portions of these steps may be used with portions of other steps from other methods, and all or portions of a step may be optional.

In method 420, a step 422 monitors environmental maintenance modules to receive operational data relative to heat transfer capacity. Step 422 may be done in real time or may be done by gathering stored data from the environmental maintenance modules. The operational data may be raw data from sensors of the environmental maintenance modules, or may be one or more operational health and/or self-diagnostic metrics provided by the environmental maintenance modules. An example of step 422 is receiving data from any of sensors 222, 224, 226, 260 and/or 270, FIG. 2, or receiving one or more operational health and/or self-diagnostic metrics provided thereby.

A step 424 determines an operational weight Wᵢ for each of the environmental maintenance modules based on the operational data. Like step 404 of method 400 above, an example of step 424 is calculating the operational weights from the operational data, utilizing a lookup table to determine the operational weights from the operational data, or comparing the operational data with one or more thresholds to determine the operational weights Wᵢ.

A step 426 computes an available heat transfer capacity based on a sum of the operational weights multiplied by the respective design capacities of the environmental maintenance modules. An example of step 426 is multiplying the operational weight Wᵢ for each environmental maintenance module by the design capacity of that module, and adding together the products to form a value of Sₕ (Eq. 4). Sₕ is the effective amount of available heat transfer capacity at the system level; that is, Sₕ is an operational value, not a design assumption.

A step 428 determines a required capacity in terms of heat transfer, for the system to maintain the selected environmental variable within a specified range, given a system load. The load may be measured or estimated. An example of step 428 is calculating a load L (Eq. 3) expressed as a number of environmental maintenance modules required to maintain the selected environmental variable.

A step 430 of method 420 calculates an operational redundancy value based on a difference between the available heat transfer capacity, from step 426, and the required capacity, using information from step 428. One example of step 430 is subtracting design capacities of the environmental maintenance modules needed to meet load L, from Sₕ to form a redundancy value RVₕ as per Eq. 6 above. That is, first environmental maintenance module design capacities Cᵢ, in units of heat transfer, from the smallest to larger design capacity modules, are summed until the total exceeds L. The sum is then subtracted from Sₕ to yield RVₕ, as per Eq. 6.

Method 420 optionally returns to step 422 after step 430, but in embodiments, an optional step 432 divides operational redundancy value RVₕ by a total of the designed heat capacities of the environmental maintenance modules, to express the operational redundancy as a percentage of designed capacity, RV_{c}. It will be appreciated that since the total of the design heat capacities is a constant for a given system (e.g., is unaffected by operational health of the environmental maintenance modules), this amounts to scaling RVₕ and expressing it in different units (e.g., percentage) as RV_{c}.

Method 420 optionally returns to step 422 after optional step 432, but in embodiments, an optional step 434 provides a message based on the operational redundancy value RVₕ. In embodiments, the message is simply storage of the calculated operational redundancy value RVₕ; alternatively, the message may be display of RVₕ, and/or an alert based thereon, to an operator of the system. If optional step 434 is performed, method 420 thereafter returns to step 422.

FIG. 4C is a flowchart that illustrates a method 440 for calculating and utilizing an operational redundancy value RVᵤ according to Eq. 7 above, that is, a calculation of redundant environmental maintenance modules available to maintain a selected environmental variable, expressed as a percentage, given operational health of the modules and the current load presented to them. Like methods 400 and 420, method 440 may be partially or totally performed with a computer system including one or more processors, modules, circuits, or other means configured to perform the steps thereof. Method 440 and/or a computer system configured to perform its steps may potentially use different components to perform a respective step or group of steps at a same time or in a different order, portions of these steps may be used with portions of other steps from other methods, and all or portions of a step may be optional.

A step 442 monitors environmental maintenance modules to receive operational data. Step 442 may be done in real time or may be done by gathering stored data from the environmental maintenance modules. The operational data may be raw data from sensors of the environmental maintenance modules, or may be one or more operational health and/or self-diagnostic metrics provided by the environmental maintenance modules. An example of step 442 is receiving data from any of sensors 222, 224, 226, 260 and/or 270, FIG. 2, or receiving one or more operational health and/or self-diagnostic metrics provided thereby.

A step 444 determines an operational weight Wᵢ for each of the environmental maintenance modules based on the operational data. An example of step 444 is calculating the operational weights from the operational data, utilizing a lookup table to determine the operational weights from the operational data, or comparing the operational data with one or more thresholds to determine the operational weights Wᵢ.

A step 446 computes available system capacity based on a sum of the operational weights. An example of step 446 is adding together the operational weights to form a value of S (Eq. 1). S is the effective number of cooling units that are operating to some minimal performance standard; that is, S is an operational value, not a design assumption.

A step 448 determines a required capacity to maintain an environmental value within a specified range, given a system load. The load may be measured or estimated. An example of step 448 is calculating a load L (Eq. 3) of environmental maintenance modules required to maintain the environmental value.

A step 450 of method 440 calculates an operational redundancy percentage based on a difference between the available capacity from step 446, and the required capacity, and dividing this difference by the total number of environmental maintenance modules. One example of step 450 is subtracting L from S to form redundancy value, and dividing by T, to form RVᵤ (as per Eq. 7 above). It will be appreciated that since the total number of environmental maintenance modules is a constant for a given system (e.g., is unaffected by operational health of the environmental maintenance modules), this amounts to scaling RV and expressing it in different units (e.g., percentage) as RVᵤ.

Method 440 optionally returns to step 442 after step 450, but in embodiments, an optional step 452 provides a message based on the operational redundancy value. In embodiments, the message is simply storage of the calculated operational redundancy value; alternatively, the message may be display of the operational redundancy value, and/or an alert based thereon, to an operator of the system. If optional step 452 is performed, method 440 thereafter returns to step 442.

### VI. Examples and Pseudocode for Calculating Operational Redundancy Value RV

The following sections provide examples of operational redundancy calculations according to Eqs. 1-8 above.

### A. Example 1

A room has 13 direct-expansion (DX) cooling units. Thus T, the total number of cooling units available, is equal to 13. During a one-week period, average heat extraction rate from the 13 cooling units is H=927 kW. The coefficients of performance (COPs) of the 13 cooling units over that week are 1.44, 1.96, 2.33, 2.75, 2.93, 2.98, 3.08, 3.65, 3.80, 3.88, 4.00 and 4.19 respectively. The design capacities of the units corresponding to the COP values are 115, 79, 79, 79, 79, 68, 88, 68, 68, 79, 68, 79 and 115 kW respectively. This data will be used to calculate RV, RVₕ, RVᵤ and RV_{c} as described above.

First, an operational redundancy calculation based on number of redundant cooling units will be illustrated. According to Eq. 3 above, L=12 because the sum of the design capacity of the 11 smallest units is 834 kW (less than H) while the sum of the design capacity of the 12 smallest units is 949 kW (greater than H). Based on the capacity and design of these units, the minimum COP specified by ASHRAE Standard 90.1 is 2.1. By this metric, the units with COPs of 1.44 and 1.96 are poorly performing. Using a value of 2.1 for a minimum performance threshold MinStdCOP, and a binary function for the weights Wᵢ, such that Wᵢ=1 when COP>MinStdCOP, otherwise Wᵢ=0, the number of healthy units, using Eq. 1 above, is S=11. Then, using Eq. 4 above, RV=11−12=−1.

Next, an operational redundancy calculation based on excess cooling capacity is illustrated. In this example, using Eq. 5 above, the available cooling capacity in heat transfer units Sₕ=870 kW (the design capacities of the poorly performing units are not counted). Then, using Eq. 6 above, an operational redundancy value in units of heat transfer is RVₕ=870−949=−79 kW.

Next, an operational redundancy calculation based on percent of total units is illustrated. Using S, L and T as defined above, operational redundancy value in percent of total units is RVᵤ=(11−12)/13=−7.7%.

Next, an operational redundancy calculation based on total cooling capacity is illustrated. RVₕ is calculated as −79 kW just above, and the total sum of design capacities is 1064 kW. Thus, using Eq. 8 above, an operational redundancy value in units of percent total cooling capacity is RV_{c}=−79/1064=−7.4%.

In each of the above examples, since the operational redundancy values are negative, the risk level is high; poorly performing cooling units are required to get the heat out of the room.

### B. Example 2

If the two poorly performing units in Example 1 degrade in a way that causes their power consumption rates to be reduced in proportion to their degraded heat extraction rates, h, then the COPs of those units may stay above the MinStdCOP threshold of 2.1. This might happen in a dual-fan, dual-compressor unit if both a fan and a compressor fail at the same time. One way to handle this case is to declare such a unit as failed, and set its weight to something less than unity (e.g., zero) in the redundancy calculation. Another way to account for this type of failure is to use an improved calculation that may use a different performance metric than COP. In an embodiment, one alternative performance metric to COP is an expected heat extraction rate. The expected heat extraction rate could be a function of exogenous variables such as return air temperature of the cooling unit, power consumption of the cooling unit (if the cooling unit contains compressor(s)), outdoor air temperature (if the cooling unit rejects heat directly through a condenser), chilled water temperature (if the cooling unit rejects heat to a chiller plant), and/or condenser water temperature (if the cooling unit rejects heat to a dry cooler or cooling tower). For a cooling unit with compressorized cooling, such as a direct-expansion cooling unit, the following equation represents the expected heat transfer rate:

hₛ=COP_{d}Pƒₒ(OAT)ƒᵣ(RAT) Eq. 12

where hₑ is the expected heat transfer rate, COP_{d} is the coefficient of performance at the design operating point, P is the power consumption of the cooling unit, fₒ( ) is a function that captures the effect of outdoor air temperature on the capacity of the unit, OAT is the outdoor air temperature, fᵣ( ) is a function that captures the effect of return air temperature on the capacity of the unit, and RAT is the return air temperature.

For a cooling unit with chilled water cooling, the following equation represents the expected heat transfer rate:

hₑ=Cƒ_{c}(ChWT,Vlv)ƒᵣ(RAT) Eq. 13

where C is the heat extraction rate at the design operating point (i.e., design capacity), f_{c}( ) is a function that captures the effect of chilled water temperature and chilled water valve position on unit capacity, ChWT is the chilled water temperature, and Vlv is the chilled water valve position.

When using expected heat extraction rate, the weights in certain redundancy calculations (e.g., Wᵢ in Eq. 1, Eq. 5) are computed as a function of expected and actual heat extraction rates. For example, weights Wᵢ could be binary functions where Wᵢ=0 if hᵢ<Pct*hₑ, and Wᵢ=1 otherwise, where Pct is a configurable percentage (e.g., 75%).

### C. Example 3

A room has two cooling units, A and B. Cooling unit A has a design capacity of 68 kW and cooling unit B has a design capacity of 115 kW. H=90 kW. In this example, even if the COPs of both units are greater than the MinStdCOP of 2.1, RV=0 because a single failure (unit B) would cause a high-temperature condition.

### D. Example 4

RV is designed to be a measure of performance-weighted redundancy that is correlated with a risk of failure. To demonstrate this correlation, RV was computed for 146 rooms, using a 1-week averaging window for cooling rate and power averages. There were 16 instances where RV was negative (a qualitatively High level of risk), 17 instances where RV had a value between 0 and an as-designed level of redundancy (a Medium level of risk), and 113 cases where RV was greater than the as-designed level of redundancy (a Low level of risk). All of these calculations were performed based on historical data from the same 1-week time window.

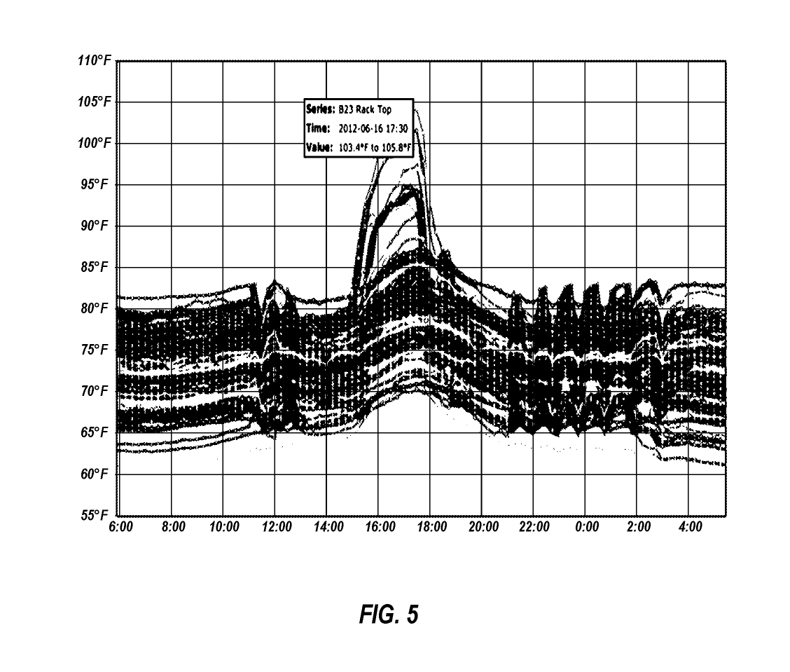

Then, a much longer historical period was searched for extreme-temperature events, where such an event was defined as one sensor reading above 100° F. while 5 or more additional sensors were reading above 90° F. FIG. 5 is a temperature vs. time plot that illustrates an example of one of these extreme-temperature events. Nine (9) of these events were found in the population of 146 rooms. RV was computed based on the historical data, week by week for several weeks leading up to each of these failure events. For the nine extreme-temperature events, the qualitative value of RV for the week, as defined above, prior to the failure was High in 3 cases, Medium in 3 cases, and Low in 3 cases.

The odds of getting this outcome by chance are low. For example, if Medium and High are combined into a single Risky category, then the probability of either 6 or more of the 9 rooms with an extreme-temperature event being categorized as Risky when the general population of rooms is Risky just 23% of the time (33 out of 146), is just 0.006, or 0.6%. This demonstrates that a low RV value is an indicator of elevated risk of an extreme-temperature event.

### E. Exemplary Pseudocode for Cop, Load and RV Calculations

The following pseudocode illustrates exemplary formulas and strategies for calculating relevant items such as COP, Load and RV. This pseudocode is not necessarily intended to be executable code (although certain programming environments may, in fact, be able to execute it). Rather, this pseudocode will be understood by one skilled in the art to illustrate relevant calculations and definitions of variables utilized in the calculations according to certain embodiments.

| | |
|---|---|
| # | Example Pseudo code for evaluating COP, Load and RV |
| # | Dictionaries of data: |
| # | hourTrends (later passed along as “trends”)= all the data the routine draws upon. |
| # | Dictionary structure is: (OID stands for object identifier): |
| # | TrendOID1 -> Timestamp1 -> (avg, min, max) |
| # | Timestamp2 -> (avg, min, max) |
| # | TrendOID2 -> Timestamp1 -> (avg, min, max) |
| # | All point types (RAT, DAT, Power) are included in this dictionary. The variable type |
| # | “HourTrends” is not to be taken literally, because this analysis can be done using |
| # | different time intervals such as, but not limited to, hour long trends, 5 minute trends, and |
| # | 15 minute trends. Timestamp is the point in time the trend sample starts (for example, for |
| # | 15 minute trends, timestamps would be “12:00, not 12:15, 12:30, etc...″) the type of |
| # | trend (hour, 5 min, 15 min etc...) |
| # | Loop over every ahu in the control group |
| # | a = shortcut for ahu.Name (units: string) |
| # | ahu = custom python object that contains all the attributes describing any given AHU in |
| # | the monitored space. (i.e. ahu.designCap is the design capacity field associated with the |
| # | ahu object.) (units: N/A) |

for a, ahu in group.ahus.iteritems( ):

| | |
|---|---|
| # | Increase Unit count and group design capacity count. |
| # | numUnits = total number of AHUs available in the group (units: integer count of units) |
| # | totalCapacity = total design capacity of all units in the group (units: BTU) |
| # | ahu.designCap = the design capacity for a given AHU. (units: BTU/hr) |
| | numUnits += 1 |
| | totalCapacity += ahu.designCap |
| # | Pass AHU config info and historic Return and Discharge Air Temperature |
| # | readings, along with Power consumption. Return is average COP and Load |
| # | over analysis period. HourTrends is a dictionary where the key is an ID for |
| # | What is being trended and the value is another dictionary where the key is a |
| # | timestamp representing the sample, and the value is the sample data, with values |
| # | of at least min value during the sample, max value during the sample, and |
| # | average value during the sample. |
| # | unitCOP = measured COP of a particular AHU (units: ratio kWt/kWe) |
| # | load = measured cooling load of a particular AHU (units: kWt) |
| | unitCOP, load = cop(ahu, hourTrends) |
| # | Error handling, if there is no COP or load calculated, critical data for |
| # | the unit is missing. Otherwise, load consumption over time period is used |
| # | to calculate overall heat load removed in the space. |
| # | noData = integer count of units that we were never able to collect data from (due to dead |
| # | sensors etc...) (units: integer count) |
| # | itLoad = measured cooling load of all cooling units in a group (units: kWt) |
| | if unitCOP == None or load == None: |
| | noData += 1 |
| | else: |
| | itLoad += load |
| # | Define threshold for determining whether or not a unit is ′good′ based on its |
| # | design Capacity values. |
| | if ahu.designCap < 65001: |
| | thresh = 2.09 |
| | elif ahu.designCap < 240001: |
| | thresh = 1.99 |
| | else: |
| | thresh = 1.79 |
| # | If COP and load are 0, unit was never on within the analyzed time frame. |
| | if (unitCOP == 0) and (load == 00): |
| | neverOn += 1 |
| # | Otherwise, if average COP is below acceptable threshold, mark unit as ′bad′ |
| # | failingUnits = integer count of all units in a group that did not pass the COP threshold test |
| # | and will be subsequently marked as “poor performers″. (units: integer count) |
| # | thresh = threshold for determining poorly performing units. (units: COP) |
| | elif (unitCOP <= thresh): |
| | failingUnits+=1 |
| # | Calculate how many units are required, how many are redundant, and compute RV from |
| # | that canFail calculates a ′runway′ of how many units can fail before failed units are |
| # | necessary to cool the space. (RV using slightly different metric) |

canFail = (totalCapacity-(itLoad*1.2))/(float(totalCapacity)/float(numUnits))
required = roundup(itLoad/(float(totalCapacity)/float(numUnits)))
redundant = roundup((itLoad*0.25)/(float(totalCapacity)/float(numUnits)))
RV = numUnits - required - redundant

| | |
|---|---|
| # | Calculates COP for an AHU, returns a duple of COP and Load. |
| # | onTimes = list of timestamps for which a particular AHU was on (on is defined as being |
| # | ON during the ENTIRETY of a trend sample) (units: list of timestamps) |
| # | offTimes = list of timestamps for which a particular AHU was off (off being defined as |
| # | being OFF during ANY POINT of a given trend sample) (units: list of timestamps) |

def cop(ahu, trends):

| | |
|---|---|
| | onTimes = [ ] |
| | offTimes = [ ] |
| # | If power monitoring not set up, return None as analysis is not possible. |
| # | ahu.points = attribute of the ahu object. list of OIDs for points (RAT/DAT/Power/etc..) |
| # | associated with that AHU. (units: list of OIDs (object Identifiers)) |
| | if ′Power Monitor′ not in ahu.points: |
| | return None, None |
| # | Begin collecting timestamps of trend samples where the module is ON. |
| # | powerOID = OID of power trend for a given AHU (units: OID (technically integer)) |
| # | totPower = total power draw of a given unit across all trend samples (units: kWe) |
| # | powerCount = number of trend samples that a unit was ON (redundant, could have used |
| # | len(onTimes)) (units: integer count) |
| | powerOID = ahu.points[′Power Monitor′].trendOID |
| | totPower = 0 |
| | powerCount = 0 |
| | if powerOID not in trends: |
| # | AHU has no power monitoring and cannot be analyzed |
| | return None, None |
| # | If unit is on during trend sample, update list of ″ON″ time samples and increment |
| # | total power consumption by average power consumed over that trend sample. |
| | for timestamp, trend in trends[powerOID].iteritems( ): |
| | if trend[1] > 0.3: |
| | onTimes.append(timestamp) |
| | powerCount += 1 |
| | totPower += trend[0] |
| | else: |
| | offTimes.append(timestamp) |
| # | If unit was on during analysis period, calculate average power consumed by that unit and |
| # | percent of analysis period that the unit was on. |
| # | avgPower = average power draw of a particular AHU across all on times (units: kWe) |
| # | onRatio = percent of total samples that can be described as “on times” (1 being 100% of |
| # | samples) (units: float between 0 and 1) |
| # | load (as used in the cop Method) = cooling load of a unit across entire sample period |
| # | (units: BTU) (it gets converted to kWt when sent back to the main loop) |
| | if powerCount > 0: |
| | avgPower = totPower/powerCount |
| | onRatio = float(len(onTimes))/float(len(onTimes) + len(offTimes)) |
| | load = coolingLoad(ahu, trends, onTimes) |
| | if not load: |
| # | There was no Return Or Discharge temperature data and analysis is not |
| # | possible. |
| | return None, None |
| # | The 3414 is used for Unit conversion (BTU vs kW) |
| | cop = (load/3412)/avgPower |
| # | Return a duple of COP and avg cooling output over the analysis period. |
| | return cop, (load*onRatio) |
| | else: |
| # | AHU was never on |
| | return 0,0 |
| # | Calculates cooling load for an AHU given trended data and a list of eligible time stamps |
| # | based off of power data |
| # | totRat = sum of all Return Air Temperatures during all samples for which a particular |
| # | AHU was “ON” (units: degF (C if needed, see comment about temp conversion in code)) |
| # | tatDat = sum of all Discharge Air Temperatures during all samples for which a particular |
| # | AHU was “ON” (units: degF (C if needed, see comment about temp conversion in code)) |
| # | ratCount = total number of “on time” samples for which there is a valid RAT reading |
| # | (units: integer count) |
| # | datCount = total number of “on time” samples for which there is a valid DAT reading |
| # | (units: integer count) |

def coolingLoad(ahu, trends, timestamps):

| | |
|---|---|
| # | Determine correct trend IDs for the given AHU. |
| | ratOID = ahu.points[′Return Air′].trendOID |
| | datOID = ahu.points[′Discharge Air′].trendOID |
| | if (ratOID not in trends) or (datOID not in trends): |
| # | Point is missing and unit cannot be analyzed. |
| | return None |
| | totRat = 0 |
| | totDat = 0 |
| | ratCount = 0 |
| | datCount = 0 |
| # | Loop over times where the unit is running |
| # | timestamps = list of “on times” for a particular AHU (units: list of timestamps) |
| # | time = one particular timestamp (units: timestamp) |
| | for time in timestamps: |
| # | Do error checking and if data is within reasonable range, add it to the list of |
| # | reasonable RAT/DAT dictionaries. |
| | if time in trends[ratOID]: |
| | if (trends[ratOID][time][0] < 100) and (trends[ratOID][time][0] > 20): |
| | totRat += trends[ratOID][time][0] |
| | ratCount += 1 |
| | if time in trends[datOID]: |
| | if (trends[datOID][time][0] < 100) and (trends[datOID][time][0] > 20): |
| | totDat += trends[datOID][time][0] |
| | datCount += 1 |
| | if ratCount == 0 or datCount == 0: |
| # | There is no return or discharge data and unit cannot be analyzed |
| | return None |
| | else: |
| # | Calculate average return and discharge temperatures for the duration of the on periods |
| # | avgRat = average RAT over all “on times” (units: degF (C if needed, see comment about |
| # | temp conversion)) |
| # | avgDat = average DAT over all “on times” (units: degF (C if needed, see comment about |
| # | temp conversion)) |

flow (ahu.designFlow) = design Flow of a given AHU (units: CFM)

| | |
|---|---|
| | avgRat = totRat/ratCount |
| | avgDat = totDat/datCount |
| | flow = ahu.designFlow |
| # | Calculate and return average load of the unit. (if needed, uncomment conversion from C |
| # | to F) |
| | load = (avgRat-avgDat)*flow*1.08 #*(9.0/5.0) |
| | return load |

### VII. Computer System

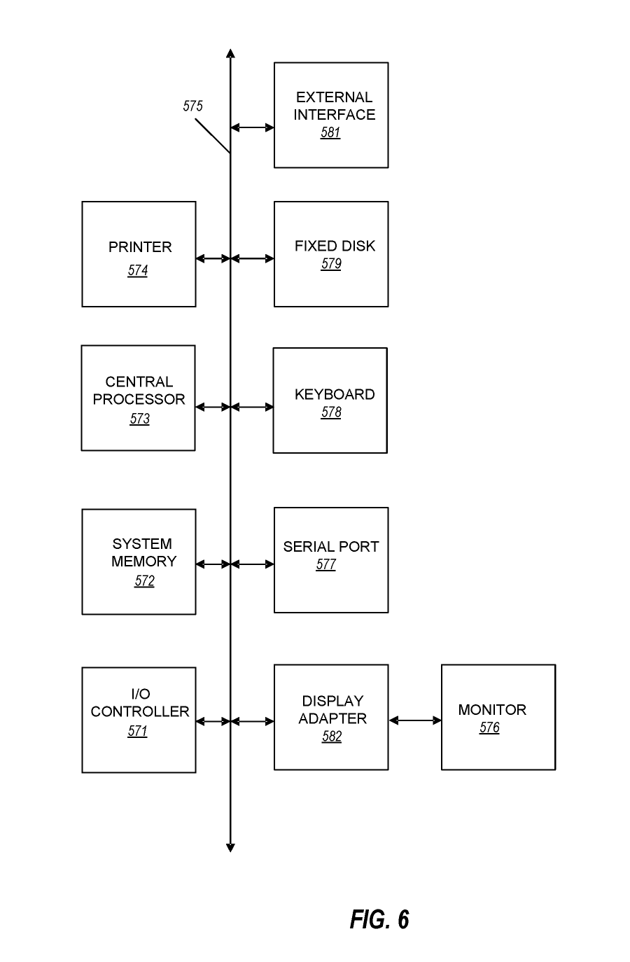

The techniques detailed above may be implemented using systems such as a control system, computer, or controller. Any of the control systems, computers, or controllers may utilize any suitable number of subsystems. Examples of such subsystems or components are shown in FIG. 6. The subsystems shown in FIG. 6 are interconnected via a system bus 575. Additional subsystems such as a printer 574, keyboard 578, storage device(s) 579, monitor 576, which is coupled to display adapter 582, and others are shown. Peripherals and input/output (I/O) devices, which couple to I/O controller 571, can be connected to the computer system by any number of means known in the art, such as serial port 577 (e.g., USB, FireWire®). For example, serial port 577 or external interface 581 (e.g. Ethernet, Wi-Fi, etc.) can be used to connect the computer apparatus to a wide area network such as the Internet, a mouse input device, or a scanner. The interconnection via system bus allows the central processor 573 to communicate with each subsystem and to control the execution of instructions from system memory 572 or the storage device(s) 79 (e.g., a fixed disk, such as a hard drive or optical disk), as well as the exchange of information between subsystems. The system memory 572 and/or the fixed disk 579 may embody a computer readable medium. Any of the data mentioned herein can be output from one component to another component and can be output to the user.

A computer system can include a plurality of the same components or subsystems, e.g., connected together by external interface 581 or by an internal interface. In some embodiments, computer systems, subsystem, or apparatuses can communicate over a network. In such instances, one computer can be considered a client and another computer a server, where each can be part of a same computer system. A client and a server can each include multiple systems, subsystems, or components.

It should be understood that any of the embodiments of the present invention can be implemented in the form of control logic using hardware (e.g. an application specific integrated circuit or field programmable gate array) and/or using computer software with a generally programmable processor in a modular or integrated manner. As used herein, a processor includes a multi-core processor on a same integrated chip, or multiple processing units on a single circuit board or networked. Based on the disclosure and teachings provided herein, a person of ordinary skill in the art will know and appreciate other ways and/or methods to implement embodiments of the present invention using hardware and a combination of hardware and software.

Any of the software components or functions described in this application may be implemented as software code to be executed by a processor using any suitable computer language such as, for example, Java, C, C++, C# or scripting language such as Perl or Python using, for example, conventional or object-oriented techniques. The software code may be stored as a plurality or series of instructions or commands on a computer readable medium for storage and/or transmission, suitable media include random access memory (RAM), a read only memory (ROM), a magnetic medium such as a hard-drive or a floppy disk, or an optical medium such as a compact disk (CD) or DVD (digital versatile disk), flash memory, and the like. The computer readable medium may be any combination of such storage or transmission devices.

Such programs may also be encoded and transmitted using carrier signals adapted for transmission via wired, optical, and/or wireless networks conforming to a variety of protocols, including the Internet. As such, a computer readable medium according to an embodiment of the present invention may be created using a data signal encoded with such programs. Computer readable media encoded with the program code may be packaged with a compatible device or provided separately from other devices (e.g., via Internet download). Any such computer readable medium may reside on or within a single computer program product (e.g. a hard drive or an entire computer system), and may be present on or within different computer program products within a system or network.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

It should be apparent that various different modifications can be made to embodiments without departing from the scope and spirit of this disclosure. In particular, the techniques and calculations disclosed herein may be adapted to any kind of system that utilizes multiple units in parallel toward a common system goal. Examples include cooling systems, heating systems, material processing or treatment systems, power distribution systems, manufacturing systems, data processing systems, and transportation systems.

A recitation of “a”, “an” or “the” is intended to mean “one or more” unless specifically indicated to the contrary. The use of “or” is intended to mean an “inclusive or,” and not an “exclusive or” unless specifically indicated to the contrary.

The above description of exemplary embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated.

What is claimed is:

1. A method of obtaining an operational redundancy value for a system including a plurality of environmental maintenance modules for maintaining an environmental value within a specified range, the method comprising performing, by a computer system:
monitoring the plurality of environmental maintenance modules, while the environmental maintenance modules are running, to receive operational data regarding a level of operation of each of the plurality of environmental maintenance modules;
determining an operational weight for each of the plurality of environmental maintenance modules based on the operational data of each of the environmental maintenance modules;
computing an available capacity metric for the system based on the operational weights of the plurality of environmental maintenance modules;
determining a required capacity for the system to maintain the environmental value within the specified range when a load exists for the plurality of environmental maintenance modules;
calculating the operational redundancy value based on the available capacity metric and the required capacity; and
providing a message based on the operational redundancy value.

2. The method of claim 1, wherein:
the environmental value is a temperature of a space served by the plurality of environmental maintenance modules; and
the load is an amount of heat that must be added to or removed from the space to maintain the temperature within the specified range.

3. The method of claim 2, wherein:
the environmental maintenance modules are cooling modules; and
the load is an amount of heat that must be removed from the space to maintain the temperature within the specified range.

4. The method of claim 3, wherein each of the cooling modules has an identical heat extraction design specification, and the operational redundancy value is a operational weights of the environmental maintenance modules.

5. The method of claim 3, wherein:
at least two of the environmental maintenance modules have heat extraction design specifications that are different from one another;
determining the required capacity for the system to maintain the environmental value within the specified range when the load exists comprises forming a sum of individual heat extraction design specifications of the environmental maintenance modules in order from smallest to largest until the sum of the individual heat extraction design specifications exceeds the load, a number of environmental maintenance modules included in the sum of individual heat extraction design specifications being a number of the environmental maintenance modules required to achieve the environmental value; and
the operational redundancy value is a difference between a total number of the environmental maintenance modules, and the number of the environmental maintenance modules required to achieve the environmental value.

6. The method of claim 1, wherein calculating the operational redundancy value comprises subtracting the required capacity from the available capacity metric.

7. The method of claim 6, further comprising dividing the operational redundancy value by a total number of the plurality of the environmental maintenance modules, to express the operational redundancy value as a fraction of the total number.

8. The method of claim 1, wherein calculating the operational redundancy value comprises:
multiplying a design capacity of each environmental maintenance module by the operational weight for the same environmental maintenance module, to form the available capacity metric for the system;
forming a sum of the design capacities of the environmental maintenance modules by adding the design capacities from smallest to largest until the sum exceeds the required capacity; and
subtracting the sum of the design capacities from the available capacity metric for the system to form the operational redundancy value.

9. The method of claim 8, further comprising dividing the operational redundancy value by a sum of the design capacities of all of the environmental maintenance modules, to express the operational redundancy value as a fraction of the total design capacity of the system.

10. The method of claim 1, wherein determining the operational weight for each of the plurality of environmental maintenance modules comprises assigning each of the operational weights as a value ranging from zero to one based on the operational data for the each of the plurality of environmental maintenance modules, and calculating the available capacity metric comprises summing the operational weights to form the available capacity metric.

11. The method of claim 1, further comprising assigning an alert level to the system based on comparing the operational redundancy value to one or more thresholds, and including the alert level in the message.

12. The method of claim 1, further comprising repeating, over time, the:
monitoring the plurality of environmental maintenance modules,
determining the operational weight for each of the plurality of environmental maintenance modules,
computing the available capacity metric for the system based on the operational weights of the plurality of environmental maintenance modules,
determining the required capacity for the system to maintain the environmental value, and
calculating the operational redundancy value; and further comprising:
assigning an alert level to the system; and
including the alert level in the message when the alert level is one of a selected subset of alert levels.

13. The method of claim 1, wherein monitoring the plurality of environmental maintenance modules comprises receiving data from one or more sensors of the environmental maintenance modules, the one or more sensors providing information of one or more of temperature and power consumption.

14. The method of claim 1, wherein monitoring the plurality of environmental maintenance modules comprises receiving one or more of health check and self-diagnostic information from the environmental maintenance modules.

15. A computer product comprising a computer readable medium storing a plurality of instructions for controlling a computer system to perform an operation for a system including a plurality of environmental maintenance modules for maintaining an environmental value within a specified range, the operation comprising:
monitoring the plurality of environmental maintenance modules, while the environmental maintenance modules are running, to receive operational data regarding a level of operation of each of the plurality of environmental maintenance modules;
determining an operational weight for each of the plurality of environmental maintenance modules based on the operational data of each of the environmental maintenance modules;
computing an available capacity metric for the system based on the operational weights of the plurality of environmental maintenance modules;
determining a required capacity for the system to maintain the environmental value within the specified range when a load exists for the plurality of environmental maintenance modules;
calculating the operational redundancy value based on the available capacity metric and the required capacity; and
providing a message based on the operational redundancy value.

16. A system for maintaining an environmental value within a specified range, comprising:
a plurality of environmental maintenance modules, wherein each of the environmental maintenance modules generates operational data; and
one or more processors configured to:
monitor the plurality of environmental maintenance modules, while the environmental maintenance modules are running, to receive operational data regarding a level of operation of each of the plurality of environmental maintenance modules;
determine an operational weight for each of the plurality of environmental maintenance modules based on the operational data of each of the environmental maintenance modules;
compute an available capacity metric for the system based on the operational weights of the plurality of environmental maintenance modules;
determine a required capacity for the system to maintain the environmental value within the specified range when a load exists for the plurality of environmental maintenance modules;
calculate the operational redundancy value based on the available capacity metric and the required capacity; and
provide a message based on the operational redundancy value.

17. The system of claim 16, wherein:
the environmental value is a temperature of a space served by the plurality of environmental maintenance modules; and
the load is an amount of heat that must be added to or removed from the space to maintain the temperature within the specified range.

18. The system of claim 16, wherein:
the environmental maintenance modules are cooling modules;
the load is an amount of heat that must be removed from the space to maintain the temperature within the specified range;
at least two of the environmental maintenance modules have heat extraction design specifications that are different from one another;
determining the required capacity for the system to maintain the environmental value within the specified range when the load exists comprises forming a sum of individual heat extraction design specifications of the environmental maintenance modules in order from smallest to largest until the sum of the individual heat extraction design specifications exceeds the load, a number of environmental maintenance modules included in the sum of individual heat extraction design specifications being a number of the environmental maintenance modules required to achieve the environmental value; and
the operational redundancy value is a difference between a total number of the environmental maintenance modules, and the number of the environmental maintenance modules required to achieve the environmental value.

19. The system of claim 16, wherein calculating the operational redundancy value comprises:
multiplying a design capacity of each environmental maintenance module by the operational weight for the same environmental maintenance module, to form the available capacity metric for the system;
forming a sum of the design capacities of the environmental maintenance modules by adding the design capacities from smallest to largest until the sum exceeds the required capacity; and
subtracting the sum of the design capacities from the available capacity metric for the system to form the operational redundancy value.

20. The system of claim 16, further comprising repeating, over time, the:
monitoring the plurality of environmental maintenance modules,
determining the operational weight for each of the plurality of environmental maintenance modules,
computing the available capacity metric for the system based on the operational weights of the plurality of environmental maintenance modules,
determining the required capacity for the system to maintain the environmental value, and
calculating the operational redundancy value; and further comprising:
assigning an alert level to the system; and
including the alert level in the message when the alert level is one of a selected subset of alert levels.
